(19) United States
(12) Patent Application Publication
(10) Pub. No.: US 2019/0016930 A1
(43) Pub. Date: Jan. 17, 2019

(54) ADHESIVE COMPOSITION

(71) Applicant: DEXERIALS CORPORATION, Tokyo (JP)

(72) Inventors: Hidetsugu NAMIKI, Tochigi (JP); Tomoyuki ISHIMATSU, Tochigi (JP); Takashi MATSUMURA, Tochigi (JP); Masaharu AOKI, Tochigi (JP)

(73) Assignee: DEXERIALS CORPORATION, Tokyo (JP)

(21) Appl. No.: 16/068,206

(22) PCT Filed: Dec. 19, 2016
(86) PCT No.: PCT/JP2016/087810

§ 371 Date: Jul. 5, 2018

(30) Foreign Application Priority Data
Jan. 5, 2016 (JP) 2016-000658

(51) Int. Cl. C09J 9/02; C09J 11/04; C09J 11/08; C09J 11/06; C09J 163/00; H01L 33/62; H01L 33/60

(52) U.S. Cl. CPC C09J 9/02; C09J 11/04; C09J 11/08; H01L 33/60; C09J 163/00; H01L 33/62; C09J 11/06

(57) ABSTRACT

An adhesive composition having excellent life properties is provided. This adhesive composition achieves excellent life properties by containing an epoxy compound, an aluminum chelating agent, and a hindered amine compound. This is presumably because the aluminum chelating agent stably exists due to the coordination of the nitrogen atom of the hindered amine compound with aluminum of the aluminum chelating agent.

### TECHNICAL FIELD

The present disclosure relates to an adhesive composition obtained by cationic polymerization of an epoxy compound by using an aluminum chelating agent. This application claims priority to Japanese Patent Application No. 2016-000658 filed on Jan. 5, 2016 in Japan, the entire content of which is hereby incorporated by reference.

### BACKGROUND ART

Conventionally, aluminum chelating agents are known as a curing agent exhibiting low-temperature rapid curing activity to epoxy compounds. For example, PLT 1 discloses an aluminum chelate-based latent curing agent retaining an aluminum chelating agent in a porous resin obtained by interfacial polymerization of a polyfunctional isocyanate compound.

However, even if the aluminum chelating agent is held in the porous resin, the aluminum chelating agent may exude from the porous resin, degrading life properties of the adhesive composition.

### CITATION LIST

### Patent Literature

PLT 1: Japanese Unexamined Patent Application Publication No, 2009-197206

### SUMMARY OF INVENTION

### Technical Problem

An object of the present disclosure is to solve the above-described problems in the prior art and to provide an adhesive composition having excellent life properties.

### Solution to Problem

As a result of intensive studies, the present inventors found that excellent life properties can be obtained by blending a hindered amine compound.

That is, an adhesive composition according to the present disclosure contains an epoxy compound, an aluminum chelating agent and a hindered amine compound.

Further, the light emitting device according to the present disclosure includes a substrate having a wiring pattern; an anisotropic conductive film formed on an electrode of the wiring pattern; and a light emitting element mounted on the anisotropic conductive film, wherein the anisotropic conductive film is a cured product of an anisotropic conductive adhesive containing an epoxy compound, an aluminum chelating agent, and a hindered amine compound.

### Advantageous Effects of Invention

According to the present disclosure, excellent life properties can be obtained by blending a hindered amine compound. This is presumably because the aluminum chelating agent stably exists due to the coordination of the nitrogen atom of the hindered amine compound with aluminum of the aluminum chelating agent. In addition, the adhesive composition according to the present disclosure is optimal for mounting light emitting elements such as LEDs since light deterioration is suppressed by radical scavenging of the hindered amine compound.

### BRIEF DESCRIPTION OF DRAWINGS

FIG. 1 illustrates a cross-sectional view of an example of a light-emitting device.

### DESCRIPTION OF EMBODIMENTS

Embodiments of the present disclosure will now be more particularly described according to the following order with reference to the accompanying drawings.
1. Adhesive Composition
2. Light Emitting Device
3. Examples

### 1. ADHESIVE COMPOSITION

An adhesive composition according to the present embodiment contains an epoxy compound, an aluminum chelating agent, and a hindered amine compound. This improves life properties. This is presumably because the aluminum chelating agent stably exists due to the coordination of the nitrogen atom of the hindered amine compound with aluminum of the aluminum chelating agent.

Epoxy Compound

Examples of the epoxy compound include bisphenol type epoxy resin derived from epichlorohydrin and bisphenol A or bisphenol F, alicyclic epoxy compound, polyglycidyl ether, polyglycidyl ester, aromatic epoxy compounds, novolak type epoxy compounds, glycidyl amine type epoxy compounds, and glycidyl ester type epoxy compound, among others; these may be used individually or in a combination of two or more. Among these, it is preferable to use a hydrogenated epoxy compound or an alicyclic epoxy compound which unlikely causes an addition reaction at the β-position carbon by a silanolate anion described later.

As the hydrogenated epoxy compound, a hydrogenated product of the above-described alicyclic epoxy compound and a hydrogenated epoxy compound obtained by hydrogenating a known epoxy compound such as bisphenol A or bisphenol F can be used. Examples of preferable alicyclic epoxy compounds include those having two or more epoxy groups per molecule. These may be liquid or solid. Particularly, examples include 3,4-epoxycyclohexenylmethyl-3,4-epoxycyclohexene carboxylate and glycidyl hexahydrobisphenol A, among others.

Among these, in view of ensuring appropriate transparency in a cured product, for example, a mounted LED (Light Emitting Diode) element and fast curability, a hydrogenated bisphenol A type epoxy resin is preferably used. Examples of commercially available products of hydrogenated bisphenol A type epoxy resin includes YX-8000, YX-8034 (manufactured by Mitsubishi Chemical Corporation), EXA-7015 (manufactured by DIC Corporation), and ST 3000 (manufactured by Toho Kasei Co., Ltd.), among others; these may be used individually or in a combination of two or more.

Aluminum Chelating Agent

As the aluminum chelating agent, a known aluminum chelating agent can be used; for example, it is preferable to use a complex compound represented by Formula (1) in which three β-ketoenolate anions are coordinated to aluminum.

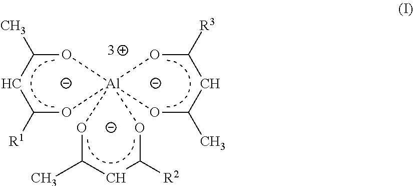

Here, R¹, R² and R³ are each independently an alkyl group or an alkoxyl group. Examples of the alkyl group include a methyl group and an ethyl group. Examples of the alkoxyl group include a methoxy group, an ethoxy group, and an oleyloxy group, among others.

Examples of the aluminum chelating agent represented by Formula (1) include aluminum tris(acetylacetonate), aluminum tris(ethylacetoacetate), aluminum monoacetylacetonate bis(ethyl acetoacetate), aluminum monoacetylacetonate bis-oleylacetoacetate, ethyl acetoacetate aluminum diisopropylate, and alkyl acetoacetate aluminum diisopropylate, among others.

Aluminum Chelating Latent Curing Agent

The aluminum chelating agent is preferably an aluminum chelating latent curing agent held in a porous resin obtained by interfacial polymerization of a polyfunctional isocyanate compound. This aluminum chelating latent curing agent can greatly improve storage stability even while directly blended with the adhesive composition as a single liquid because the aluminum chelating agent is held in a large number of fine pores existing in the porous resin matrix.

This aluminum chelating latent caring agent can be obtained by dissolving an aluminum chelating agent and a polyfunctional isocyanate compound in a volatile organic solvent, introducing the obtained solution into an aqueous phase containing a dispersant, and heating and stirring for interfacial polymerization. Specifically, the aluminum chelating latent curing agent can be obtained by dissolving an aluminum chelating agent and a polyfunctional isocyanate compound having a weight more than twice that of the aluminum chelating agent in 100 to 500 parts by mass of a lower alkyl acetic ester per 100 parts by mass in total of the aluminum chelating agent and the polyfunctional isocyanate compound, adjusting the viscosity of the obtained solution to 1 to 2.5 mPa*s, introducing the solution into the aqueous phase containing the dispersant, and heating and stirring it for interfacial polymerization.

The polyfunctional isocyanate compound preferably has two or more isocyanate groups per molecule and more preferably has three isocyanate groups per molecule. Examples of the trifunctional isocyanate compound include a TMP adduct of Formula (2) obtained by reacting 1 mol of trimethylolpropane with 3 mol of a diisocyanate compound, an isocyanurate compound of Formula (3) obtained by self-condensing 3 mol of a diisocyanate compound, and a purette product of Formula (4) obtained by condensing diisocyanate urea obtained from 2 mol of 3 mol of the diisocyanate compound with the remaining 1 mole of a diisocyanate, among others.

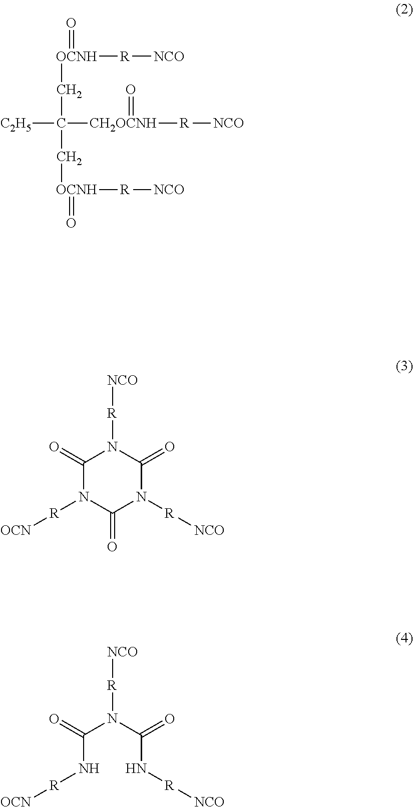

In the above formulas (2) to (4), the substituent R is a moiety excluding the isocyanate group of the diisocyanate compound. Examples of the diisocyanate compound include toluene 2,4-diisocyanate, toluene 2,6-diisocyanate, m-xylylene diisocyanate, hexamethylene diisocyanate, hexahydro-m-xylylene diisocyanate, and isophorone diisocyanate, methylene diphenyl-4,4′-diisocyanate, among others.

The aluminum chelating agent is preferably an aluminum chelating latent curing agent held in a porous resin obtained by interfacial polymerization of a polyfunctional isocyanate compound and simultaneous radical polymerization of divinylbenzene. By allowing divinylbenzene to coexist at the time of interfacial polymerization of the polyfunctional isocyanate compound, the exothermic peak temperature can be shifted to a low temperature, thus improving the low-temperature rapid curability.

This aluminum chelating latent curing agent can be obtained by dissolving an aluminum chelating agent, a polyfunctional isocyanate compound, a radical polymerizable compound, and a radical polymerization initiator in a volatile organic solvent, introducing the obtained solution into an aqueous phase containing a dispersant, and heating and stirring it for interfacial polymerization.

Aluminum Chelate—Silanol Curing Catalyst System

As represented in the following formulas (5) and (6), the aluminum chelating agent is preferably an aluminum chelate-silanol curing catalyst system in which, in cooperation with a silanol compound or a silane coupling agent, a cationic species and an anionic species are generated to cationically polymerize an epoxy compound.

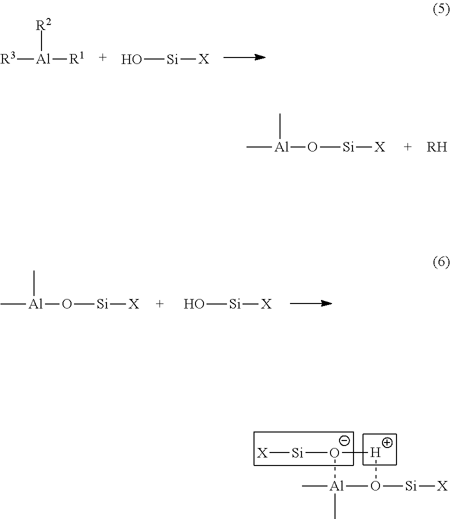

An example of the silanol compound includes an arylsilanole represented by Formula (7).

(Ar)ₘSi(OH)ₙ (7)

In this formula, m is 2 or 3, with the proviso that the sum of in and n is 4. The silanol compound represented by Formula (7) is a mono- or diol form, “Ar” is an aryl group which may be substituted. Examples of the aryl group include phenyl, naphthyl, anthracenyl, azulenyl, fluorenyl, thienyl, furyl, pyrrolyl, imidazolyl and pyridyl groups. Among these, a phenyl group is preferable from the viewpoints of availability and cost of acquisition. Each of the m aryl groups Ar may be the same or different and is preferably the same from the viewpoint of availability.

These aryl groups can have 1 to 3 substituents including halogen such as chloro and bromo; trifluoromethyl; nitro; sulfo; alkoxycarbonyl such as carboxyl, methoxycarbonyl, ethoxycarbonyl; alkyl such as an electron withdrawing group such as formyl, or methyl, ethyl, propyl; alkoxy such as methoxy, ethoxy; hydroxy; amino; monoalkylamino such as monomethylamino; and electron donating groups, for example, dialkylamino such as dimethylamino. Note that it is possible to control the curing activity since using an electron-withdrawing group as a substituent can increase acidity of the hydroxyl group of silanol, and conversely, using an electron donating group can decrease the acidity. Here, substituents may be different for each of m aryl groups, but from the viewpoint of availability for m aryl groups, the substituents are preferably the same. In addition, only a part of Ar may have a substituent, and other Ar may have no substituent.

Among the silanol compounds of formula (7), preferred are triphenylsilanol and diphenylsilanol. Among these, triphenylsilanol is especially preferred.

It is also preferable to impregnate the silanol compound into an aluminum chelating latent curing agent in which an aluminum chelating agent is held in a porous resin obtained by interfacial polymerization of a polyfunctional isocyanate compound, or in which an aluminum chelating agent is held in a porous resin obtained by interfacial polymerization of a polyfunctional isocyanate compound and simultaneous radical polymerization of divinylbenzene. Low-temperature rapid curability can be improved by impregnating the aluminum chelating latent curing agent with the silanol compound,

An example of the method of impregnating a silanol compound includes dispersing an aluminum chelate-based latent curing agent in an organic solvent (for example, ethanol), adding a silanol compound of Formula (7) (for example, triphenylsilanol) and optionally an aluminum chelate curing agent (for example, an isopropanol solution of monoacetylacetonate bis (ethylacetoacetate)) to the dispersion, and stirring this for several hours to overnight at a temperature of about room temperature to about 50° C.

In addition, the aluminum chelate-silanol curing catalyst system may contain a silane coupling agent. The silane coupling agent has a function of initiating cationic polymerization in cooperation with an aluminum chelating agent, particularly an aluminum chelating latent curing agent. The molecule of silane coupling agent preferably includes 1 to 3 lower alkoxy groups and a group having reactivity with the functional group of the cationically polymerizable resin, such as a phenyl group, a styryl group, an acryloyloxy group, a methacryloyloxy group, an epoxy group, or an amino group. It should be noted that the coupling agent having an amino group can be used in the case where the generated cationic species of the aluminum chelate-silanol curing catalyst system is not substantially captured.

Examples of the silane coupling agent include vinyltris(β-methoxyethoxy) silane, vinyl triethoxysilane, vinyl trimethoxysilane, γ-styryltrimethoxysilane, γ-methacryloxypropyltrimethoxysilane, γ-acryloxypropyltrimethoxysilane, β-(3,4-epoxycyclohexyl) ethyltrimethoxysilane, γ-glycidoxypropyltrimethoxysilane, γ-glycidoxypropylmethyldiethoxysilane, N-β-(aminoethyl)-γ-aminopropyltrimethoxysilane, N-β-(aminoethyl)-γ-aminopropylmethyldimethoxysilane, γ-aminopropyltriethoxysilane, N-phenyl-γ-aminopropyltrimethoxysilane, and γ-chloropropyltrimethoxysilane.

The content of the silane coupling agent is 1 to 300 parts by mass, preferably 1 to 100 parts by mass with respect to 100 parts by mass of the aluminum chelate type latent curing agent since there is a tendency that the effect of addition does not appear when the content of the slime coupling agent is insufficient, and the influence of the polymerization termination reaction by the silanolate anion generated from the silane coupling agent occurs when the content is excessive.

Such an aluminum chelate-silanol curing catalyst system has inferior life properties since cation species and anion species coexist as active species; however, excellent life properties can be achieved by blending a hindered amine compound. This is presumably because the aluminum chelating agent stably exists due to the coordination of the nitrogen atom of the hindered amine compound with aluminum of the aluminum chelating agent.

Hindered Amine Compound

The hindered amine compound shifts the exothermic onset temperature of the adhesive composition to higher temperatures, thereby improving the latency and the life properties. This is presumably because the aluminum chelating agent stably exists due to the coordination of the nitrogen atom of the hindered amine compound with aluminum of the aluminum chelating agent.

An example of the hindered amine compound includes a hindered amine light stabilizer (HALS: Hindered Amine Light Stabilizer) having a 2,2,6,6-tetramethylpiperidine skeleton. Examples of the hindered amine light stabilizer include N—H type, N—R type, and N—OR type.

Specific examples of the N—H type hindered amine type stabilizer include tetrakis (1,2,2,6,6-pentamethyl-4-piperidyl) butane-1,2,3,4-butanetetracarboxylate (ADK STAB LA-57 manufactured by ADEKA), bis (2,2,6,6,-tetramethyl-4-piperidyl) sebacate (TINUVIN 770 DF manufactured by BASF), N,N′-bis (2,2,6,6-tetramethyl-4-piperidyl)-N,N′-diformylhexamethylenediamine (UVINUL 4050 FF manufactured by BASF), polycondensate of dibutylamine 1,3,5-triazine N,N′-bis (2,2,6,6-tetramethyl-4-piperidyl)-1,6-hexamethylenediamine and N-(2,2,6,6-tetramethyl-4-piperidyl)butylamine (Chimassorb 2020 FDL manufactured by BASF), poly [(6-(1,1,3,3-tetramethylbutyl) amino-1,3,5-triazine-2,4-diyl} {(2,2,6,6-tetramethyl-4-piperidyl) Imino} hexamethylene {(2,2,6,6-tetramethyl-4-piperidyl) imino)] (Chimassorb 944 FDL manufactured by BASF), and olefin (C20-C24) maleic anhydride 4-amino-2,2,6,6-tetramethylpiperidine copolymer (UVINUL 5050H manufactured by BASF).

Specific examples of the N—R type hindered amine type stabilizer include bis (1,2,2,6,6-pentamethyl-4-piperidyl)[[3,5-bis(1,1-dimethylethyl)-4-hydroxyphenyl] methyl] butylmalonate (TINUVIN 144 manufactured by BASF), bis (1,2,2,6,6-pentamethyl-4-piperidyl) sebacate and methyl 1,2,2,6,6-pentamethyl-4-piperidyl sebacate (mixture) (TINUVIN 765 manufactured by BASE), polycondensate of succinic acid and dimethyl-1-(2-hydroxyethyl)-4-hydroxy-2,2,6,6-tetramethylpiperidine (TINUVIN 622 SF from BASF), N,N′-bis (3-aminopropyl) ethylenediamine-2,4-bis [N-butyl-N-(1,2,2,6,6-pentamethyl-4-piperidyl)amino]-6-chloro-1,3,5-triazine condensate (SABOSTABUV 119 manufactured by SABO S.R.L), tetrakis (1,2,2,6,6-pentamethyl-4-piperidyl) 1,2,3,4-butanetetracarboxylate (ADK STAB LA-52 manufactured by ADEKA), 1,2,2,6,6-pentamethyl-4-piperidyl/tridecyl 1,2,3,4 butane tetracarboxylate (ADK STAB LA-62 manufactured by ADEKA), mixed esters of 1,2,3,4-butanetetracarboxylic acid, 1,2,2,6,6-pentamethyl-4-piperidinol and 3,9-bis(2-hydroxy-1,1-dimethylethyl)-2,4,8,10 tetraoxaspiro [5,5] undecane (ADK STAB LA-63 manufactured by ADEKA), condensate of tetrakis(2,2,6,6-tetramethyl-4-piperidyl)-1,2,3,4-butanetetracarboxylate, 1,2,3,4-butanetetracarboxylic acid, 1,2,2,6,6-pentamethyl-4-piperidinol, and tridecyl alcohol (ADK STAB LA-63P, manufactured by ADEKA), 1,2,2,6,6-pentamethyl-4-piperidyl methacrylate.

Specific examples of the N—OR type hindered amine type stabilizer include NOR type hindered amine light stabilizer system (TINUVIN XT 850 FF manufactured by BASF), weather resistant stabilizer system based on NOR type hindered amine light stabilizer system (TINUVIN 855 FF manufactured by BASF), reaction product of 4-butylamino-2,2,6,6-tetramethylpiperidine with peroxidation, and 2,4,6-trichloro-1,3,5-triazine, and cyclohexane, N,N′-ethane-1,2-diylbis(1,3-propanediamine) (Flamestab NOR 116 FF manufactured by BASF), bis (1-undecanoxy-2,2,6,6-tetramethylpiperidin-4-yl) carbonate (LA-81 manufactured by ADEKA).

The above-mentioned hindered amine light stabilizers can be used individually or in a combination of two or more. Among these, it is preferable to use a condensate of 1,2,3,4-butanetetracarboxylic acid which is bulky and has a large steric hindrance effect. Examples of the condensate of 1,2,3,4-butanetetracarboxylic acid include tetrakis (1,2,2,6,6-pentamethyl-4-piperidyl) 1,2,3,4-butanetetracarboxylate (ADK STAB LA-52 manufactured by ADEKA), tetrakis(1,2,2,6,6-pentamethyl-4-piperidyl) butane-1,2,3,4-butanetetracarboxylate (ADK STAB LA-57 manufactured by ADEKA), and condensate of tetrakis(2,2,6,6-tetramethyl-4-piperidyl)-1,2,3,4-butanetetracarboxylate, 1,2,3,4-butanetetracarboxylic acid, 1,2,2,6,6-pentamethyl-4-piperidinol, and tridecyl alcohol (ADK STAB LA-63P, manufactured by ADEKA).

By using a condensate of 1,2,3,4-butanetetracarboxylic acid, when an aluminum chelating latent curing agent in which an aluminum chelating agent is held in a porous resin obtained by interfacial polymerization of a polyfunctional isocyanate compound, or an aluminum chelating latent curing agent in which an aluminum chelating agent is held in a porous resin obtained by interfacial polymerization of a polyfunctional isocyanate compound and simultaneous radical polymerization of divinylbenzene is used, the exothermic onset temperature of the adhesive composition can be largely shifted to higher temperatures. This is presumably because the bulky hindered amine type compound coordinated to the aluminum chelating agent held in the porous resin, thereby stabilizing the compound and improving latency.

In addition, since the hindered amine compound also has an effect as a light stabilizer and an antioxidant, it is especially suitable as an adhesive composition for flip-chip mounting a substrate and a light emitting element which will be described later.

The content of the hindered amine compound is preferably 0.05 to 20 parts by mass with respect to 100 parts by mass in total of the epoxy compound and the aluminum chelating latent curing agent, and more preferably 0.05 to 15 parts by mass. Insufficient content of the hindered amine compound tends to preclude improvements in life properties and excessive content tends to degrade reflectance and optical properties.

Other Components

In addition, the adhesive composition according to this embodiment may contain white inorganic particles such as TiO₂, BN, ZnO, Al₂O₃ as another component in order to reflect light emitted from the LED and to obtain high light extraction efficiency. The average particle size of the white inorganic particles is preferably not less than ½ of the wavelength of the light to be reflected. Further, the content of the white inorganic particles is preferably 1 to 50 vol %, and more preferably 5 to 25 vol % with respect to the binder component.

In addition, inorganic fillers may be contained in order to control fluidity and improve the particle capturing rate. The inorganic filler is not particularly limited, but silica, talc, titanium oxide, calcium carbonate, and magnesium oxide can be used. Such an inorganic filler can be appropriately used in accordance with the purpose of alleviating the stress of the connection structure connected by the adhesive. Further, a thermoplastic resin, or a softening agent such as a rubber component may be blended.

Further, the adhesive composition may be an anisotropic conductive adhesive containing conductive particles. Any known conductive particles can be used as the conductive particles. As the conductive particles, examples include particles of metals or metal alloys such as those of nickel, iron, copper, aluminum, tin, lead, chromium, cobalt, silver or gold and particles such as those of metal oxides, carbon, graphite, glass, ceramics and plastics coated with metal, or the above-mentioned particles further coated with a thin electrically-insulating film, among others. In the case of coating a metal to the surface of resin particles, examples of usable resin particles include epoxy resin, phenol resin, acrylic resin, acrylonitrile-styrene (AS) resin, benzoguanamine resin, divinylbenzene-type resin, and styrene-type resin particles, among others. Additionally, to suppress an increase in resistance to flattening deformation of the conductive particles, the surfaces of the resin particles may be coated with Ni, among other materials. Among these, it is preferable to use conductive particles in which a metal layer is formed on the surface of resin particles. In such conductive particles, by being easily compressed and deformed during compression, contact area with wiring patterns can be increased. Furthermore, variance in wiring pattern height can be compensated.,

The average particle diameter of the conductive particles is preferably 1 μm or more and 10 μm or less, more preferably 1 μm or more and 8 μm or less. From the viewpoints of connection reliability and insulation reliability, it is preferable that the blending amount of the conductive particles is 1 parts by mass or more and 100 parts by mass or less with respect to 100 parts by mass of the binder.

It is also preferable to use conductive particles and solder particles in combination. The average particle diameter of the solder particles is preferably smaller than that of the conductive particles, and the average particle diameter of the solder particles is preferably 20% or more and less than 100% of the average particle diameter of the conductive particles. If the solder particles are too small with respect to the conductive particles, the solder particles are not trapped between the opposing terminals at the time of crimping and are not metal bonded, so excellent heat dissipation properties and electrical properties cannot be achieved. On the contrary, when the solder particles are too large with respect to the conductive particles, for example, shoulder touch by solder particles occurs at the edge portion of the LED chip, causing leaks which degrade product yields.

Solder particles can be selected as appropriate in accordance with electrode material and connection conditions from, for example, as defined in JIS Z 3282-1999, Sn—Pb, Pb—Sn—Sb, Sn—Sb, Sn—Pb—Bi, Bi—Sn, Sn—Cu, Sn—Pb—Cu, Sn—In, Sn—Ag, Sn—Pb—Ag, and Pb—Ag types, among others. In addition, shape of the solder particles can be selected as appropriate from granular shapes and flake shapes, among others. It should be noted that, in order to improve anisotropic properties, the solder particles may be covered with an insulating layer.

Blending amount of the solder particles is preferably 1% to 30% by volume. An insufficient blending amount of the solder particles leads to excellent heat dissipation properties being unobtainable; an excessive blending amount impairs anisotropic properties, thereby making excellent connection reliability unobtainable.

In such an adhesive composition, the exothermic onset temperature measured by a differential scanning calorimetry at a heating rate of 10° C./min is preferably 80 to 90° C., the exothermic peak temperature is preferably 100 to 120° C., and the reaction end point temperature is preferably 180 to 220° C. Shifting the exothermic onset temperature of the adhesive composition to a higher temperature by the addition of the hindered amine compound can improve latency and achieve excellent conductivity.

### 2. LIGHT EMITTING DEVICE

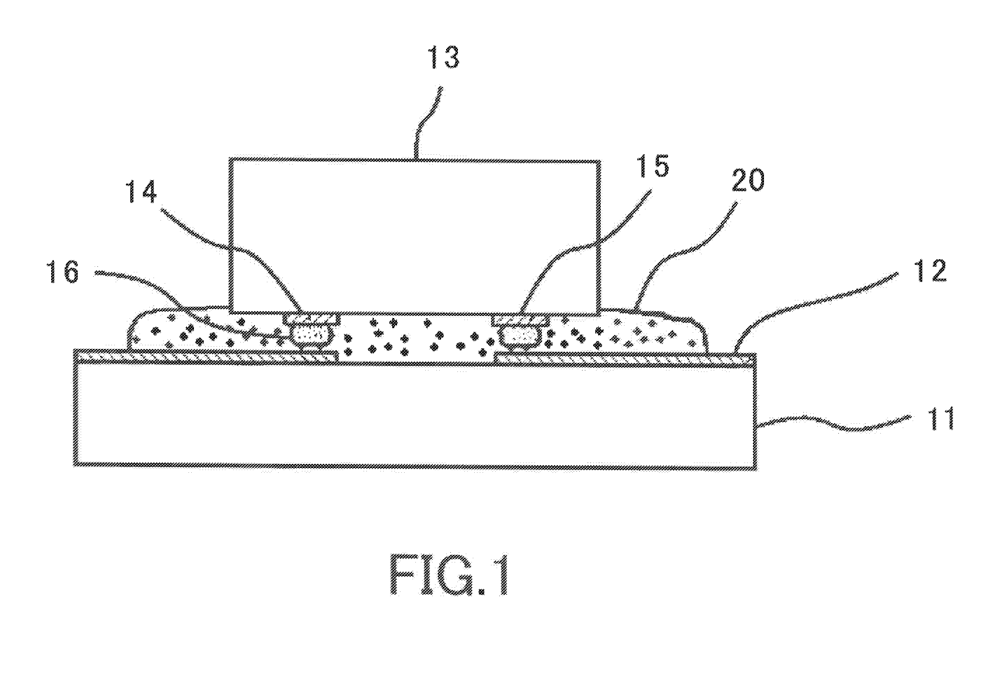

Next, a light-emitting device according to the present disclosure will be described. FIG. 1 is a cross-sectional view showing an example of a light-emitting device. The light emitting device includes a substrate 11 having a wiring pattern 12, an anisotropic conductive film 20 formed on electrodes of the wiring pattern 12, and a light emitting element 13 mounted on the anisotropic conductive film 20; the conductive film 20 is made of a cured product of the above-mentioned anisotropic conductive adhesive. This light emitting device can be obtained by applying the aforementioned anisotropic conductive adhesive between the wiring pattern 12 on the substrate 11 and the connection bumps 16 formed on each of the n electrode 14 and the p electrode 15 of the LED element as the light emitting element 13, and then flip chip mounting the light emitting element 13 onto the substrate 11.

In the present embodiment, by using the above-mentioned anisotropic conductive adhesive, the hindered amine compound exhibits an effect as a light stabilizer and an antioxidant, and high reflectance and excellent optical characteristics can be obtained.

If necessary, the LED element 13 may be sealed with a transparent mold resin so as to cover the entire LED element 13. Further, a light reflecting layer may be provided on the LED element 13. In addition to the LED element, any known light emitting element can be used as the light emitting element, as long as the effect of the present disclosure is not impaired.

### 3. EXAMPLES

### Examples

Hereinafter, examples of the present disc sure will be described. In these examples, anisotropic conductive adhesives containing a hindered amine light stabilizer were prepared. Then, exothermic onset temperatures, exothermic peak temperatures, and exothermic end pint temperatures of the anisotropic conductive adhesives were measured. Also, the viscosity lives and reflectances of the anisotropic conductive adhesives were evaluated. In addition, LED packages were fabricated by mounting an LED chip on a substrate by using the anisotropic conductive adhesives, optical and electric characteristics were evaluated. It should be noted that the present invention is not limited to these examples.

Measurement of Exothermic Onset Temperature and Exothermic Peak Temperature of Anisotropic Conductive Adhesive

The exothermic onset temperatures, exothermic peak temperatures, and exothermic end point temperatures of the anisotropic conductive adhesives were measured at a heating rate of 10° C./min using a differential scanning calorimeter (DSC). Regarding curing characteristics, the exothermic onset temperature means the curing starting temperature, the exothermic peak temperature means the temperature at which the curing is most active, the exothermic end point temperature means the curing ending temperature, and peak area means heating value.

Measurement of Viscosity Life

Using a HAAKE rheometer, the initial viscosities of the anisotropic conductive adhesives immediately after fabrication were measured. Further, the anisotropic conductive adhesives were left for 48 hours in an environment of a temperature of 25° C. and a humidity of 60%, and then the viscosity of the anisotropic conductive adhesives were measured. Then, viscosity increase ratios (times increase) between initial viscosity and viscosity after subjecting to an environment of 25° C. and 60% humidity for 48 hours were calculated for the anisotropic conductive adhesives.

Measurement of Reflectance

Anisotropic conductive adhesives were applied to a white plate made of ceramic so as to have a thickness of 100 μm and heated at a temperature of 200° C. for 60 seconds for curing. Initial cured products were measured for reflectance (JIS K 7150) at a wavelength of 450 nm using a spectrophotometer. The products were then irradiated with UV for 100 hours, and reflectance of the cured products after the UV-irradiation test was measured in the same manner.

Fabrication of LED Package

LED packages were obtained by applying an anisotropic conductive adhesive to the LED mounting substrate (ceramic substrate) in which the pitch between conductors (Ni (5.0 μm)/Au (0.3 μm) plating wiring) is 100 μm, and then aligning, mounting, and thermocompression bonding a blue LED chip (Vf=3.1 V (If=350 mA), size: 1.0 mm×1.0 mm) in which the electrode is formed of an AuSn alloy with a thickness of 3 μm onto the substrate. Thermocompression bonding conditions were 200° C. for 60 seconds with a pressure of 1 kg/chip.

Measurement of Optical Characteristic

Initial total luminous fluxes (lm) of the LED package were measured using a total luminous flux measuring device (LE-2100, manufactured by Otsuka Electronics Co., Ltd.) using an integrating sphere. The total luminous fluxes (lm) were measured after the LED packages were lighted for 1,000 hours at If=350 mA under an environment of a temperature of 85° C. and a humidity of 85% (reliability test). The measurement condition of the total luminous flux was set to If=350 mA (constant current control).

Evaluation of Electrical Characteristics

Initial Vf values of the LED packages were measured at If=350 mA. Vf values were measured at If=350 mA after lighting the LED packages for 1,000 hours at If=350 mA under an environment of 85° C. and 85% humidity (reliability test). In evaluating conductivity, the Vf average value was set to 3.10 V; LED packages having a Vf value of less than 3.15 V were evaluated as “A”, LED packages having a Vf value of 3.15 V or more and less than 3.6 V were evaluated as “B”, and LED packages having a Vf value of 3.6 V or more were evaluated as “C”.

### Example 1

A binder was prepared by blending 1.0 parts by mass of a hindered amine light stabilizer (product name: LA-52, manufactured by ADEKA. Co., Ltd.) with respect to 100 parts by mass in total of 95 parts by mass of a hydrogenated bisphenol A type epoxy resin (product name: YX 8000, manufactured by Mitsubishi Chemical Corporation) and 5 parts by mass of an aluminum chelating latent curing agent. To this binder, 2 vol % of conductive particles (resin core, Au plating) having an average particle diameter (D50) of 5.5 μm, 5 vol % of solder particles (product name: M 705 (Sn-3.0 Ag-0.5 Cu), mp: 214° C., manufactured by Senju Metal Industry Co., Ltd.) having an average particle diameter (D50) of 5.0 μm, and 10 vol % of titanium oxide having an average particle diameter (D50) of 0.25 μm were dispersed, to prepare an anisotropic conductive adhesive.

The aluminum chelating latent curing agent was prepared as follows. First, 800 parts by mass of distilled water, 0.05 parts by mass of a surfactant (NEW=R-T, NOF Corporation), and 4 parts by mass of polyvinyl alcohol (PVA-205, Kuraray Co., Ltd.) as a dispersant were placed in a 3-liter interfacial polymerization vessel equipped with a thermometer and mixed uniformly. In addition, an oil phase solution in which 100 parts by mass of a 24% isopropanol solution of aluminum monoacetylacetonate bis (ethylacetoacetate) (aluminum chelate D, Kawaken Fine Chemicals Co., Ltd.), 70 parts by mass of trimethylolpropane (1 mol) adduct (D-109, Mitsui Takeda Chemicals, Inc.) of methylene diphenyl-4,4′-diisocyanate (3 mol), 30 parts by mass of divinylbenzene (Merck & Co., Inc.), and 0.30 parts by mass of a radical polymerization initiator (Peroyl L, NOF CORPORATION) dissolve in 100 parts by mass of ethyl acetate was added to this mixed solution before emulsifying and mixing with a homogenizer (10,000 rpm/5 minutes) followed by interfacial polymerization at 80° C. for 6 hours. After completion of the reaction, the polymerization reaction solution was allowed to cool to room temperature, and the interfacial polymerization particles were filtered and air dried. Thus, 100 parts by mass of a spherical latent curing agent having a particle diameter of about 2 μm, was obtained in which the aluminum chelating agent interfacially polymerizes the polyfunctional isocyanate compound and, at the same time, is held in a porous resin obtained by radical polymerization of divinylbenzene.

After 10 parts by mass of this latent curing agent was added to a mixture of 40 parts by mass of a 24% isopropanol solution of aluminum monoacetylacetonate bis (ethyl acetoacetate) (aluminum chelate D, Kawaken Fine Chemicals Co., Ltd.), 20 parts by mass of triphenylsilanol, and 40 parts by mass of ethanol, this mixture was stirred at 40° C. overnight, filtered, and dried to obtain an aluminum chelating latent curing agent impregnated with triphenylsilanol.

As shown in Table 1, the anisotropic conductive adhesive had an exothermic onset temperature of 85° C., an exothermic peak temperature of 113° C., and a reaction end point temperature of 205° C. The viscosity increase rate of the anisotropic conductive adhesive at room temperature for 48 h was 1.0 times. The initial reflectance of the anisotropic conductive adhesive was 65%, and the reflectance after 100 h UV irradiation was 63%. Further, the initial total luminous flux of the LED package was 7.0 lm, and the total luminous flux after the reliability test was 7.0 lm. Also, the initial conductivity evaluation of the LED package was A, and the conductivity evaluation after the reliability test was A.

### Example 2

With the exception that 0.05 parts by mass of a hindered amine light stabilizer (product name: LA-52, manufactured by ADEKA) was blended to 100 parts by mass in total of 95 parts by mass of hydrogenated bisphenol A type epoxy resin (product name: YX 8000, manufactured by Mitsubishi Chemical Corporation) and 5 parts by mass of the aluminum chelating latent curing agent to prepare the binder, an anisotropic conductive adhesive was prepared in the same manner as in Example 1.

As shown in Table 1, the anisotropic conductive adhesive had an exothermic onset temperature of 85° C., an exothermic peak temperature of 113° C., and a reaction end point temperature of 205° C. The viscosity increase rate of the anisotropic conductive adhesive at room temperature for 48 h was 1.0 times. The initial reflectance of the anisotropic conductive adhesive was 65%, and the reflectance after 100 h UV irradiation was 63%, Further, the initial total luminous flux of the LED package was 7.0 lm, and the total luminous flux after the reliability test was 7.0 lm. Also, the initial conductivity evaluation of the LED package was A, and the conductivity evaluation after the reliability test was A.

### Example 3

With the exception that 10.0 parts by mass of a hindered amine light stabilizer (product name: LA-52, manufactured by ADEKA) was blended to 100 parts by mass in total of 95 parts by mass of hydrogenated bisphenol A type epoxy resin (product name: YX 8000, manufactured by Mitsubishi Chemical Corporation) and 5 parts by mass of aluminum chelating latent curing agent to prepare the binder, an anisotropic conductive adhesive was prepared in the same manner as in Example 1.

As shown in Table 1, the anisotropic conductive adhesive had an exothermic onset temperature of 85° C., an exothermic peak temperature of 113° C., and a reaction end point temperature of 205° C. The viscosity increase rate of the anisotropic conductive adhesive at room temperature for 48 h was 1.0 times. The initial reflectance of the anisotropic conductive adhesive was 65%, and the reflectance after 100 h UV irradiation was 63%. Further, the initial total luminous flux of the LED package was 7.0 lm, and the total luminous flux after the reliability test was 7.0 lm. Also, the initial conductivity evaluation of the LED package was A, and the conductivity evaluation after the reliability test was A.

### Example 4

With the exception that 1.0 parts by mass of a hindered amine light stabilizer (trade name: LA-57, manufactured by ADEKA) was blended to 100 parts by mass in total of 95 parts by mass of hydrogenated bisphenol A type epoxy resin (product name: YX 8000, manufactured by Mitsubishi Chemical Corporation) and 5 parts by mass of aluminum chelating latent curing agent to prepare the binder, an anisotropic conductive adhesive was prepared in the same manner as in Example 1.

As shown in Table 1, the anisotropic conductive adhesive had an exothermic onset temperature of 80° C., an exothermic peak temperature of 110° C., and a reaction end point temperature of 205° C. The viscosity increase rate of the anisotropic conductive adhesive at room temperature for 48 h was 1.1 times. The initial reflectance of the anisotropic conductive adhesive was 63%, and the reflectance after 100 h UV irradiation was 61%. Further, the initial total luminous flux of the LED assembly was 6.9 lm, and the total luminous flux after the reliability test was 6.8 lm. Also, the initial conductivity evaluation of the LED package was A, and the conductivity evaluation after the reliability test was A.

### Example 5

With the exception that 1.0 parts by mass of a hindered amine light stabilizer (product name: LA-63P, manufactured by ADEKA) was blended to 100 parts by mass in total of 95 parts by mass of hydrogenated bisphenol A type epoxy resin (product name: YX 8000, manufactured by Mitsubishi Chemical Corporation) and 5 parts by mass of aluminum chelating latent curing agent to prepare the binder, an anisotropic conductive adhesive was prepared in the same manner as in Example 1.

As shown in Table 1, the anisotropic conductive adhesive had an exothermic onset temperature of 88° C., an exothermic peak temperature of 115″C, and a reaction end point temperature of 205° C. The viscosity increase rate of the anisotropic conductive adhesive at room temperature for 48 h was 1.1 times. The initial reflectance of the anisotropic conductive adhesive was 64%, and the reflectance after 100 h UV irradiation was 62%. Further, the initial total luminous flux of the LED package was 6.9 lm, and the total luminous flux after the reliability test was 6.9 lm. Also, the initial conductivity evaluation of the LED package was A, and the conductivity evaluation after the reliability test was A.

### Example 6

With the exception that 20.0 parts by mass of a hindered amine light stabilizer (product name: LA.-52, manufactured by ADEKA) was blended to 100 parts by mass in total of 95 parts by mass of hydrogenated bisphenol A type epoxy resin (product name: YX 8000, manufactured by Mitsubishi Chemical Corporation) and 5 parts by mass of aluminum chelating latent curing agent to prepare the binder, an anisotropic conductive adhesive was prepared in the same manner as in Example 1.

As shown in Table 1, the anisotropic conductive adhesive had an exothermic onset temperature of 85° C., an exothermic peak temperature of 113° C., and a reaction end point temperature of 205° C. The viscosity increase rate of the anisotropic conductive adhesive at room temperature for 48 h was 1.0 times. The initial reflectance of the anisotropic conductive adhesive was 60%, and the reflectance after 100 h of UV irradiation was 50%. Further, the initial total luminous flux of the LED package was 6.0 lm, and the total luminous flux after the reliability test was 5.2 lm. Also, the initial conductivity evaluation of the LED package was A, and the conductivity evaluation after the reliability test was A.

### Comparative Example 1

An anisotropic conductive adhesive was prepared in the same manner as in Example 1 except that a binder was prepared without adding a hindered amine light stabilizer.

As shown in Table 1, the anisotropic conductive adhesive had an exothermic onset temperature of 60° C., an exothermic peak temperature of 105° C., and a reaction end point temperature of 205° C. The viscosity increase rate of the anisotropic conductive adhesive at room temperature for 48 h was 4.0 times. The initial reflectance of the anisotropic conductive adhesive was 65%, and the reflectance after the UV irradiation 100 h was 55%. Further, the initial total luminous flux of the LED package was 7.0 lm, and the total luminous flux after the reliability test was 5.5 lm. Also, the initial conductivity evaluation of the LED package was A, and the conductivity evaluation after the reliability test was A.

### Comparative Example 2

With the exception that 1.0 parts by mass of amine type curing agent (2E4MZ: 2-ethyl-4-methylimidazole) was blended to 100 parts by Mass in total of 95 parts by mass of hydrogenated bisphenol A type epoxy resin (product name: YX 8000, manufactured by Mitsubishi Chemical Corporation) and 5 parts by mass of aluminum chelating latent curing agent to prepare the binder, an anisotropic conductive adhesive was prepared in the same manner as in Example 1.

As shown in Table 1, the anisotropic conductive adhesive had an exothermic onset temperature of 70° C., an exothermic peak temperature of 110° C., and a reaction end point temperature of 205° C. The viscosity increase rate of the anisotropic conductive adhesive at room temperature for 48 hours was 2.0 times. The initial reflectance of the anisotropic conductive adhesive was 50%, and the reflectance after UV irradiation for 100 hours was 35%. Further, the initial total luminous flux of the LED package was 5.0 lm, and the total luminous flux after the reliability test was 4.0 lm. Moreover, the initial conductivity evaluation of the LED package was A, and the conductivity evaluation after the reliability test was A.

| | | Ex. 1 | Ex. 2 | Ex. 3 | Ex. 4 | Ex. 5 | Ex. 6 | Comp. 1 | Comp. 2 |
|---|---|---|---|---|---|---|---|---|---|
| hindered amine | type | LA-52 | LA-52 | LA-52 | LA-57 | LA-63P | LA-52 | — | 2E4MZ |
| | blending amount [wt %] | 1 | 0.05 | 10 | 1 | 1 | 20 | — | 1 |
| conductive particle | particle diameter [μm] | 5.5 | 5.5 | 5.5 | 5.5 | 5.5 | 5.5 | 5.5 | 5.5 |
| solder particle | particle diameter [μm] | 5 | 5 | 5 | 5 | 5 | 5 | 5 | 5 |
| white inorganic filler | type | TiO₂ | TiO₂ | TiO₂ | TiO₂ | TiO₂ | TiO₂ | TiO₂ | TiO₂ |
| | particle diameter [μm] | 0.25 | 0.25 | 0.25 | 0.25 | 0.25 | 0.25 | 0.25 | 0.25 |
| DSC | reaction onset temperature | 85 | 85 | 85 | 80 | 88 | 85 | 60 | 70 |
| | [° C.] | | | | | | | | |
| | exothermic peak temperature | 113 | 113 | 113 | 110 | 115 | 113 | 105 | 110 |
| | [° C.] | | | | | | | | |
| | reaction end point | 205 | 205 | 205 | 205 | 205 | 205 | 205 | 205 |
| | temperature [° C.] | | | | | | | | |
| viscosity life | viscosity increase rate at | 1.0 | 1.0 | 1.0 | 1.1 | 1.1 | 1.0 | 4.0 | 2.0 |
| | room temperature for 48 h | | | | | | | | |
| | [times] | | | | | | | | |
| reflectance | initial | 65 | 65 | 65 | 63 | 64 | 60 | 65 | 50 |
| | UV irradiation-100 h | 63 | 63 | 63 | 61 | 62 | 50 | 55 | 35 |
| optical characteristic | initial | 7.0 | 7.0 | 7.0 | 6.9 | 6.9 | 6.0 | 7.0 | 5.0 |
| total luminous flux | 85° C.-85% RH-1000 h lighted | 7.0 | 7.0 | 7.0 | 6.8 | 6.9 | 5.2 | 5.5 | 4.0 |
| [lm] electrical | initial | A | A | A | A | A | A | A | A |
| characteristic | 85° C.-85% RH-1000 h lighted | A | A | A | A | A | A | A | A |
| conductivity | | | | | | | | | |

When no hindered amine light stabilizer was blended as in Comparative Example 1, the rate of viscosity increase at room temperature for 48 h was 4.0 times. In addition, when amine curing agent was blended as in Comparative Example 2, the rate of viscosity increase at room temperature for 48 h was 2.0 times. On the contrary, when a hindered amine light stabilizer was blended as in Examples 1 to 6, the rate of viscosity increase at room temperature for 48 h was 1.0 to 1.1 times. This is considered to be due to the fact that the nitrogen atom of the hindered amine light stabilizer is coordinated to the aluminum of the aluminum chelate in the aluminum chelating latent curing agent and stabilized. The stabilization is also understood from the comparison between Example 1 and Comparative Example 1, that the exothermic onset temperature measured by DSC shifted to a higher temperature.

Further, as in Examples 1 to 5, when the content of the hindered amine light stabilizer is 0.05 to 15 parts by mass with respect to 100 parts by mass in total of the epoxy resin and the aluminum chelating latent curing agent, it was possible to suppress decrease in reflectance and deterioration in optical characteristics due to coloring of the cured product by the hindered amine light stabilizer.

### REFERENCE SIGNS LIST

11 substrate, 12 wiring pattern, 13 light emitting element, 14 n electrode, 15 p electrode, 16 bump, 20 anisotropic conductive film

1. An adhesive composition comprising an epoxy compound, an aluminum chelating agent, and a hindered amine compound.

2. The adhesive composition according to claim 1, wherein the aluminum chelating agent is an aluminum chelating latent curing agent held in a porous resin obtained by interfacial polymerization of a polyfunctional isocyanate compound.

3. The adhesive composition according to claim 1, wherein the aluminum chelating agent is an aluminum chelating latent curing agent that is held in a porous resin obtained by interfacial polymerization of a polyfunctional isocyanate compound and simultaneous radical polymerization of divinylbenzene.

4. The adhesive composition according to claim 2, wherein the content of the hindered amine compound is 0.05 to 15 parts by mass with respect to 100 parts by mass of the total of the epoxy compound and the aluminum chelating latent curing agent.

5. The adhesive composition according to claim 2, wherein the aluminum chelating latent curing agent is obtained by impregnating the porous resin with a silanol compound.

6. The adhesive composition according to claim 2, wherein the aluminum chelating latent curing agent is obtained by impregnating the porous resin with a silanol compound.

7. The adhesive composition according to claim 1, wherein an exothermic onset temperature measured at a heating rate of 10° C./min by a differential scanning calorimetry is 80 to 90° C.

8. The adhesive composition according to claim 2, wherein the exothermic onset temperature measured at a heating rate of 10° C./min by a differential scanning calorimetry is 80 to 90° C.

9. The adhesive composition according to claim 3, wherein the exothermic onset temperature measured at a heating rate of 10° C./min by a differential scanning calorimetry is 80 to 90° C.

10. The adhesive composition according to claim 1, wherein the hindered amine compound is a condensate of 1,2,3,4-butanetetracarboxylic acid.

11. The adhesive composition according to claim 2, wherein the hindered amine compound is a condensate of 1,2,3,4-butanetetracarboxylic acid.

12. The adhesive composition according to claim 3, wherein the hindered amine compound is a condensate of 1,2,3,4-butanetetracarboxylic acid.

13. The adhesive composition according to claim 4, wherein the hindered amine compound is a condensate of 1,2,3,4-butanetetracarboxylic acid.

14. The adhesive composition according to claim 1, further comprising a silane coupling agent.

15. The adhesive composition according to claim 1, further comprising solder particles, conductive particles, and white inorganic particles.

16. A light emitting device comprising:
a substrate having a wiring pattern;
an anisotropic conductive film formed on an electrode of the wiring pattern; and
a light emitting element mounted on the anisotropic conductive film,
wherein the anisotropic conductive film is a cured product of an anisotropic conductive adhesive containing an epoxy compound, an aluminum chelating agent, and a hindered amine compound.

17. The adhesive composition according to claim 4, wherein the content of the hindered amine compound is 0.05 to 15 parts by mass with respect to 100 parts by mass of the total of the epoxy compound and the aluminum chelating latent curing agent.

18. The adhesive composition according to claim 4, wherein the aluminum chelating latent curing agent is obtained by impregnating the porous resin with a silanol compound.

19. The adhesive composition according to claim 4, wherein the exothermic onset temperature measured at a heating rate of 10° C./min by a differential scanning calorimetry is 80 to 90° C.

20. The adhesive composition according to claim 4, wherein the hindered amine compound is a condensate of 1,2,3,4-butanetetracarboxylic acid.
